(19) United States
(12) Patent Application Publication
(10) Pub. No.: US 2025/0241171 A1
(43) Pub. Date: Jul. 24, 2025

(54) DISPLAY DEVICE

(71) Applicant: Samsung Display Co., Ltd., Yongin-Si (KR)

(72) Inventors: Wonseok Kim, Yongin-si (KR); Jueyoun Park, Yongin-si (KR); Intae Son, Yongin-si (KR); Kangwoo Lee, Yongin-si (KR); Dasong Lee, Yongin-si (KR); Hyunjung Lee, Yongin-si (KR)

(21) Appl. No.: 18/973,128

(22) Filed: Dec. 9, 2024

(30) Foreign Application Priority Data
Jan. 24, 2024 (KR) 10-2024-0011180

(51) Int. Cl. H10K 59/80; H10K 77/10

(52) U.S. Cl. CPC H10K 59/871; H10K 59/8794; H10K 77/111

(57) ABSTRACT

Provided is a display device including a display panel configured to display an image on a surface, and a cover panel on another surface of the display panel, which faces the surface of the display panel that displays the image, wherein the cover panel includes a buffer adhesive layer in which storage modulus measured at −20° C. is greater than about 0 MPa but not greater than about 10 MPa.

### CROSS-REFERENCE TO RELATED APPLICATION

This application is based on and claims priority under 35 U.S.C. § 119 to Korean Patent Application No. 10-2024-0011180, filed on Jan. 24, 2024, in the Korean Intellectual Property Office, the disclosure of which is incorporated by reference herein in its entirety.

### BACKGROUND

### Field

One or more embodiments disclosed herein relate to a display device and more particularly to a display device including a cover panel.

### Description of the Related Art

Electronic devices, such as mobile electronic devices and fixed electronic devices, are currently used in many applications, and such electronic devices often include display devices for providing visual information, such as images or videos, so as to support various functions of the electronic devices. Recently, with the miniaturization of electronic components, the proportions of the display devices in the electronic devices have increased. Display devices having structures that are bendable from flat states to have certain angles have also been developed.

A display device typically includes a display layer located on a substrate. At least a portion of the display device may be bent to improve visibility of the display layer at various angles or to reduce the footprint of a non-display area in the display device. In particular, components, such as a display circuit board, may be arranged in or on a portion of the display device that is bent to position the display circuit board behind the display area.

The aforementioned background technology may be technical information that the inventors possessed or acquired during the derivation of the disclosure and was not necessarily disclosed or known to the public before the priority date of the present patent document.

### SUMMARY

One or more embodiments disclosed herein include a display device including a display panel having a portion that is bent and a cover panel arranged below the display panel to protect the display panel.

One or more embodiments include a display device including a cover panel that is reinforced, is impact resistant, and/or has improved surface flexure.

Additional aspects are set forth in the description which follows, are apparent from the description or may be learned by practice of the embodiments disclosed herein.

According to one or more embodiments, a display device includes a display panel configured to display an image on a surface, and a cover panel on another surface of the display panel that faces the surface of the display panel that displays the image, wherein the cover panel includes a buffer adhesive layer in which storage modulus measured at −20° C. is greater than about 0 MPa but not greater than about 10 MPa.

According to an embodiment, the storage modulus of the buffer adhesive layer, measured at −40° C., may be about 2 MPa to about 30 MPa.

According to an embodiment, the buffer adhesive layer may include at least one of polyurethane acrylate, rubber, and polystyrene.

According to an embodiment, the buffer adhesive layer may include at least one of toluene diisocyanate (TDI), isoporon diisocyanate (IPDI), polypropylene glycol (PPG), and polytetramethalene ether glycol (PTMEG).

According to an embodiment, the buffer adhesive layer may contain about 0.05 wt % to about 20 wt % of the polyurethane acrylate.

According to an embodiment, the buffer adhesive layer may further include an acryl-based polymer compound.

According to an embodiment, the cover panel may further include a film layer in contact with an upper portion of the buffer adhesive layer.

According to an embodiment, the cover panel may further include a metal layer in contact with a lower portion of the buffer adhesive layer.

According to an embodiment, the metal layer may include copper (Cu).

According to an embodiment, the buffer adhesive layer may further include a pigment for blocking light.

According to an embodiment, about 3 wt % to about 5 wt % of the pigment may be included.

According to an embodiment, the buffer adhesive layer may further include a heat dissipation filler for heat dissipation.

According to an embodiment, the heat dissipation filler may include silica or alumina.

According to one or more embodiments, a display device includes a display panel that is bent in a U shape so that a first portion of the display panel and a second portion of the display panel face each other, and a cover panel between the first portion and the second portion, wherein the cover panel includes a buffer adhesive layer in which storage modulus measured at −20° C. is greater than about 0 MPa but not greater than about 10 MPa.

According to an embodiment, the storage modulus of the buffer adhesive layer, measured at −40° C., may be about 2 MPa to about 30 MPa.

According to an embodiment, the buffer adhesive layer may include at least one of polyurethane acrylate, rubber, and polystyrene.

According to an embodiment, the buffer adhesive layer may include at least one of toluene diisocyanate (TDI), isoporon diisocyanate (IPDI), polypropylene glycol (PPG), and polytetramethalene ether glycol (PTMEG).

According to an embodiment, the buffer adhesive layer may contain about 0.05 wt % to about 20 wt % of the polyurethane acrylate.

According to an embodiment, the buffer adhesive layer may further include a pigment for blocking light.

According to an embodiment, the buffer adhesive layer may further include a heat dissipation filler for heat dissipation.

Other aspects, features, and advantages other than those described above will become apparent from the detailed descriptions, claims and drawings for carrying out the following disclosure.

### BRIEF DESCRIPTION OF THE DRAWINGS

The above and other aspects, features, and advantages of certain embodiments of the disclosure will be more apparent from the following description taken in conjunction with the accompanying drawings.

FIG. 1 is a plan view of a portion of an embodiment of a display device in an unbent state.

FIG. 2 is a lateral cross-sectional view of a portion of an embodiment of a display device in a bent state.

FIG. 3 is an equivalent circuit diagram schematically showing a pixel circuit applicable to a display device, according to an embodiment.

FIG. 4 is a cross-sectional view of a portion of the display device taken along a line I-I′ shown in FIG. 1.

FIG. 5 is a cross-sectional view of a cover panel according to an embodiment.

FIG. 6 shows graphs illustrating temperature and frequency dependence of a storage modulus of a buffer adhesive layer according to an embodiment.

FIG. 7 is a graph illustrating a ball drop test of a cover panel according to an embodiment.

### DETAILED DESCRIPTION

Specific embodiments are illustrated in the drawings and are described in detail in this detailed description. Effects and features of the disclosure and methods of achieving the same will become apparent with reference to embodiments described in detail with reference to the drawings. However, the disclosure is not limited to the embodiments described below, and other embodiments may be implemented in various forms. The disclosure may have various modifications and various embodiments.

As used herein, the term “and/or” includes any and all combinations of one or more of the associated items. Throughout the disclosure, the expression “at least one of a, b, and c” indicates only a, only b, only c, both a and b, both a and c, both b and c, all of a, b, and c, or variations thereof.

The following description refers to multiple figures of the drawings, in which like reference numerals refer to like components. Redundant descriptions of like components in figures may be omitted, indicating that prior descriptions of the like components apply.

In the following, the terms “first” and “second” are not used in a limited sense and are used to distinguish one component from another component.

In the following, an expression used in the singular encompasses the expression of the plural, unless the context indicates a clearly different meaning.

In the following, the terms “comprise” and/or “comprising” specify the presence of stated features or components but do not preclude the presence or addition of one or more other features or components.

A layer, region, or element referred to herein as being “formed on” another layer, area, or element may be directly or indirectly formed on the other layer, region, or element. That is, for example, intervening layers, regions, or elements may be present.

The sizes of components may be exaggerated or reduced in the drawings for convenience of description. In other words, because sizes and thicknesses of components in the drawings may be arbitrarily illustrated, the disclosure is not necessarily limited thereto.

According to embodiments, an x-axis, a y-axis, and a z-axis are not limited to three axes on an orthogonal coordinate system but may be interpreted in a broad sense including the three axes. For example, the x-axis, the y-axis, and the z-axis may be perpendicular to one another or may represent different directions that are not perpendicular to one another.

The present disclosure may describe a specific process order for a specific embodiment, but other embodiments may be performed differently from the described order. For example, two consecutively described processes may be performed substantially at the same time or performed in an order opposite to the described order.

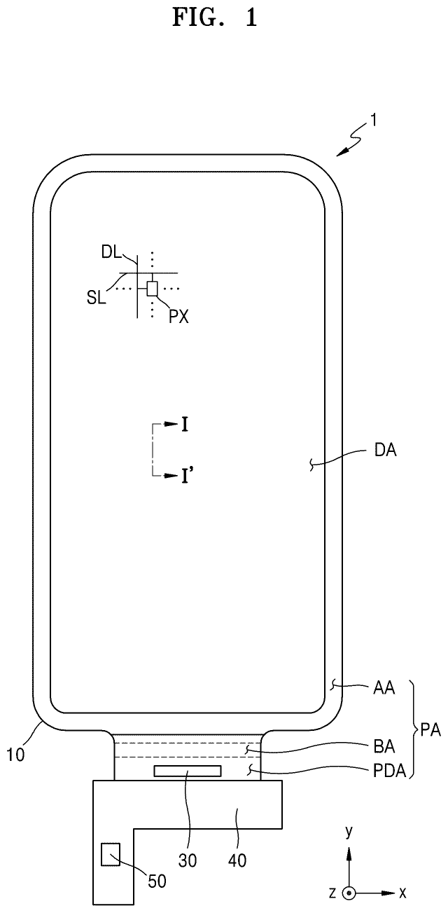

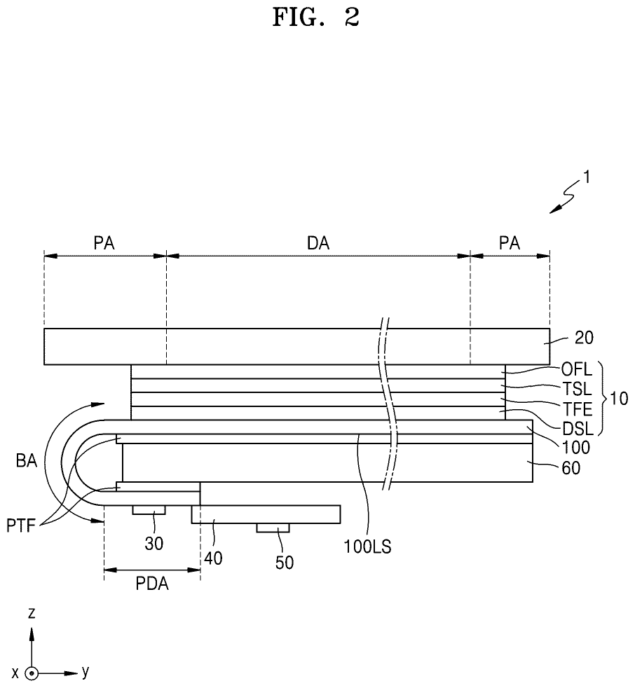

FIG. 1 is a plan view of a portion of a display device 1, according to an embodiment. FIG. 1 illustrates a display panel 10 in an unbent state for convenience of description. FIG. 2 is a lateral cross-sectional view of a portion of the display device 1, according to an embodiment. FIG. 2 illustrates the display panel 10 in a bent state.

Referring to FIGS. 1 and 2, the display device 1 is a device configured to display a moving image or a still image, and the display device 1 may be used as a display screen of not only portable electronic devices, such as a mobile phone, a smart phone, a tablet personal computer (PC), a mobile communication terminal, an electronic notebook, an electronic book, a portable multimedia player (PMP), a navigation device, and an ultra-mobile PC (UMPC), but also various products, such as a television, a laptop computer, a monitor, a billboard, and an Internet of things (IoT) device. Also, the display device 1 according to an embodiment may be used for a wearable device, such as a smart watch, a watch phone, a glasses-type display, or a head mounted display (HMD). In addition, the display device 1 according to an embodiment may be used as a panel of a vehicle, a center information display (CID) on a center fascia or dashboard of a vehicle, a mirror display replacing a side mirror of a vehicle, or a display screen on a rear surface of a front seat as entertainment for a back seat of a vehicle.

The display device 1 may have an approximately rectangular shape as shown in FIG. 1. For example, as shown in FIG. 1, the display device 1 may have an overall rectangular plane shape, which has short sides extending in a first direction (e.g., an x direction or a −x direction) and long sides extending in a second direction (e.g., a y direction or a −y direction). According to an embodiment, a corner or other portion where the short side extending in the first direction (e.g., the x direction or the −x direction) and the long side extending in the second direction (e.g., the y direction or the −y direction) meet may have a right-angled shape or a round shape with a specific curvature. The plane shape of the display device 1 is not limited to a rectangle and may be a polygon, a circle, an oval, or any other shape depending on the embodiment.

The display device 1 may include a display area DA and a peripheral area PA. The display area DA may display an image. Here, pixels PX may be arranged in the display area DA. The display device 1 may be configured to provide an image by using light emitted from the pixels PX. Each pixel PX may be configured to emit light by using a display element. According to an embodiment, each of the pixels PX may emit red, green, or blue light. According to an embodiment, each of the pixels PX may emit a red, green, blue, or white light.

The peripheral area PA may be an area that does not provide an image and may be a non-display area. The peripheral area PA may surround at least a portion of the display area DA. For example, the peripheral area PA may entirely surround the display area DA. A driver configured to provide an electrical signal to the pixels PX, a power supply wire configured to provide power, or the like may be arranged in the peripheral area PA. For example, a scan driver in the peripheral area PA may be configured to apply a scan signal to scan lines SL connected to the pixels PX. Also, a data driver in the peripheral area PA may be configured to apply a data signal to data lines DL connected to the pixels PX. According to an embodiment, the peripheral area PA may include an adjacent area AA that is adjacent to the display area DA and surround the display area DA, a bending area BA that is connected to one side of the adjacent area AA and is bent, and a pad area PDA connected to the bending area BA and where pads are arranged.

Referring to FIG. 2, the display device 1 may include the display panel 10, a cover window 20, a display driver 30, a display circuit board 40, a touch sensor driver 50, a cover panel 60, and a protection film PTF.

The display panel 10 may be configured to display information processed by the display device 1. For example, the display panel 10 may be configured to display execution screen information of an application driven by the display device 1 or user interface (UI) or graphical user interface (GUI) information according to the execution screen information.

The display panel 10 may include display elements. For example, the display panel 10 may be an organic light-emitting display panel using organic light-emitting diodes using an organic semiconductor, a micro light-emitting diode (LED) display panel using micro LEDs, a quantum dot light-emitting display panel using quantum dot LEDs including a quantum dot emission layer, or an inorganic light-emitting display panel using inorganic LEDs including an inorganic semiconductor. Hereinafter, a case in which the display panel 10 is an organic light-emitting display panel using organic light-emitting diodes as display elements is described in detail.

The display panel 10 may include a substrate 100 and a multi-layer film arranged on the substrate 100. According to an embodiment, the display panel 10 may include the substrate 100, a display layer DSL, an encapsulation layer TFE, a touch sensor layer TSL, and an optical functional layer OFL. Here, the display area DA and the peripheral area PA may define areas of the substrate 100 and/or the multi-layer film. For example, the substrate 100 may include the display area DA and the peripheral area PA. Also, the peripheral area PA of the substrate 100 may include the pad area PDA and the bending area BA.

The substrate 100 may include a polymer resin, such as polyether sulfone, polyarylate, polyetherimide, polyethylene naphthalate, polyethylene terephthalate, polyphenylene sulfide, polyimide, polycarbonate, cellulose triacetate, or cellulose acetate propionate. According to an embodiment, the substrate 100 may have a multi-layer structure including a base layer including the polymer resin described above and a barrier layer (not shown). The substrate 100 including the polymer resin may be flexible, rollable, or bendable.

The substrate 100 may be bent in the bending area BA. In this case, according to an embodiment, the substrate 100 may be bent in a U-shape in the bending area BA, and thus, at least some portions of a lower surface 100LS of the substrate 100 may face each other and the pad area PDA of the substrate 100 may be located below other portions of the substrate 100. Accordingly, only a portion of the peripheral area PA is visible to a user since part of the peripheral area PA may be behind the visible face of the display device 1. In FIG. 2, only the substrate 100 is bent, but according to another embodiment, at least a portion of the display layer DSL, at least a portion of the encapsulation layer TFE, and at least a portion of the touch sensor layer TSL may extend into the bending area BA and the pad area PDA. In which case, at least a portion of the display layer DSL, at least a portion of the encapsulation layer TFE, and at least a portion of the touch sensor layer TSL may also be bent in the bending area BA.

The display layer DSL may be disposed on the substrate 100. The display layer DSL may include pixel circuits and display elements. Here, the pixel circuits may be connected to the display elements, respectively. The pixel circuit may include a transistor and a storage capacitor. Accordingly, the display layer DSL may include a plurality of display elements, a plurality of transistors, and a plurality of storage capacitors. Also, the display layer DSL may further include conductive and semiconductive layers with insulating layers arranged therebetween.

The encapsulation layer TFE may be disposed on the display layer DSL. The encapsulation layer TFE may be disposed on the display elements and cover the display elements. According to an embodiment, the encapsulation layer TFE may include at least one inorganic encapsulation layer and at least one organic encapsulation layer. The at least one inorganic encapsulation layer may include at least one inorganic material from among aluminum oxide (Al₂O₃), titanium oxide (TiO₂), tantalum oxide (Ta₂O₅), zinc oxide (ZnO), silicon oxide (SiO₂), silicon nitride (SiNx), and silicon oxynitride (SiON). The at least one organic encapsulation layer may include a polymer-based material. Examples of the polymer-based material may include an acrylic resin, an epoxy resin, polyimide, and polyethylene. According to an embodiment, the at least one organic encapsulation layer may include acrylate.

The touch sensor layer TSL may be disposed on the encapsulation layer TFE. The touch sensor layer TSL may be used to obtain coordinate information of an external input such as a touch event. The touch sensor layer TSL may include a sensor electrodes and touch wires connected to the sensor electrodes. The touch sensor layer TSL may detect the external input via a magnetic capacitance method or a mutual capacitance method.

The touch sensor layer TSL may be formed on the encapsulation layer TFE. Alternatively, the touch sensor layer TSL may be formed separately on a touch substrate and then attached to the encapsulation layer TFE via an adhesive layer, such as an optically clear adhesive. According to an embodiment, the touch sensor layer TSL may be directly formed on the encapsulation layer TFE, and in this case, the adhesive layer may not be needed or provided between the touch sensor layer TSL and the encapsulation layer TFE.

The optical functional layer OFL may be arranged on the touch sensor layer TSL. The optical functional layer OFL may perform one or more optical functions such as reducing reflectance of light (external light) incident from the outside towards the display device 1 and/or enhancing color purity of light emitted from the display device 1. According to an embodiment, the optical functional layer OFL may include a retarder and/or a polarizer. The retarder may be a film type or liquid crystal coating type and may include a λ/2 retarder and/or a λ/4 retarder. The polarizer may also be a film type or a liquid crystal coating type. The film type polarizer may include an elongated synthetic resin film, and the liquid crystal coating type polarizer may include liquid crystals. The retarder and the polarizer may further include a protection film.

According to another embodiment, the optical functional layer OFL may include a black matrix and color filters. The color filters may be arranged according to the colors of light respectively emitted from the pixels PX of the display device 1. The color filters may each include red, green, or blue pigment or dye. Alternatively, the color filters may each further include quantum dots, in addition to the above pigment or dye. Alternatively, some of the color filters may not include the pigment or dye and may include scattered particles such as titanium oxide.

According to another embodiment, the optical functional layer OFL may include a destructive interference structure. The destructive interference structure may include a first reflective layer and a second reflective layer arranged on different layers. First reflective light and second reflective light reflected respectively from the first reflective layer and the second reflective layer may destructively interfere with each other, and accordingly, reflectance of external light may be reduced.

The cover window 20 may be disposed on the display panel 10. The cover window 20 may protect the display panel 10. According to an embodiment, the cover window 20 may be a flexible window. The cover window 20 may protect the display panel 10 by being easily bent to absorb an external force without causing a crack or the like. The cover window 20 may include at least one of glass, sapphire, and plastic. The cover window 20 may be, for example, ultra-thin glass (UTG) or colorless polyimide (CPI). According to an embodiment, the cover window 20 may have a structure in which a flexible polymer layer is arranged on one surface of a glass substrate or may include only a polymer layer.

The cover window 20 may be attached to the display panel 10 using an adhesive member. The adhesive member may be a clear adhesive member such as a layer of an optically clear adhesive (OCA). In some embodiments, the adhesive member may include various well-known adhesive materials. Various methods may be used to form the adhesive member on an upper portion of the display panel 10. For example, the adhesive member may be attached to the upper portion of the display panel 10 by being formed in a film form or may be coated on the upper portion of the display panel 10 by being formed in a material form.

The display driver 30 may attach to the pad area PDA of the substrate 100. The display driver 30 may receive control signals and power voltages and may generate and output signals and voltages for driving the display panel 10. The display driver 30 may include an integrated circuit (IC).

The display circuit board 40 may be electrically connected to the display panel 10. For example, the display circuit board 40 may be electrically connected to the pad area PDA of the substrate 100 through an anisotropic conductive film. The display circuit board 40 may be a flexible printed circuit board (FPCB) or a rigid printed circuit board (PCB). Alternatively, according to an embodiment, the display circuit board 40 may be a composite printed circuit board including both a rigid PCB and an FPCB.

The touch sensor driver 50 may be disposed on the display circuit board 40. The touch sensor driver 50 may include an IC. The touch sensor driver 50 may be attached on the display circuit board 40. The touch sensor driver 50 may be electrically connected through the display circuit board 40 to the sensor electrodes of the touch sensor layer TSL of the display panel 10.

A power supplier may be further disposed on the display circuit board 40. The power supplier may supply driving voltages for driving the pixels PX of the display panel 10 and the display driver 30.

The protection film PTF may be patterned and attached to the lower surface 100LS of the substrate 100. Here, the protection film PTF may be attached to a portion of the substrate 100 excluding the bending area BA of the substrate 100. A region of the protection film PTF may be opposite to the display layer DSL with the substrate 100 therebetween. Another region of the protection film PTF may be attached to the lower surface 100LS of the substrate 100 opposite the pad area PDA.

According to an embodiment, the cover panel 60 may be provided between the regions of the protection film PTF. In other words, the cover panel 60 may be between a portion (e.g., a first portion) and another portion (e.g., a second portion) of the substrate 100, which face each other when the substrate 100 is bent in a U-shape. The cover panel 60 may absorb an external impact to prevent the display panel 10 from being damaged.

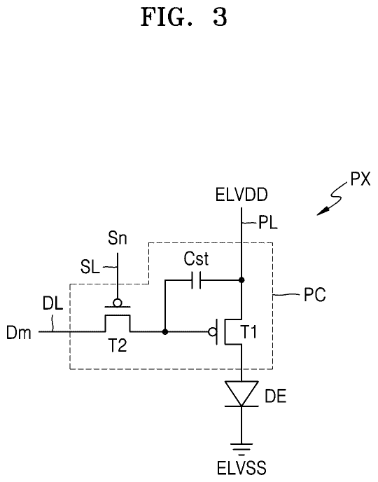

FIG. 3 is an equivalent circuit diagram schematically showing an embodiment of a pixel circuit PC applicable to the display device 1.

Referring to FIG. 3, the pixel circuit PC may be electrically connected to a display element DE. The pixel circuit PC may include a first transistor T1, a second transistor T2, and a storage capacitor Cst. According to an embodiment, the display element DE may be configured to emit red, green, or blue light or emit red, green, blue, or white light.

The second transistor T2 is connected to a scan line SL and a data line DL, and may transmit, to the first transistor T1, a data signal or data voltage Dm input from the data line DL, based on a scan signal or switching voltage Sn input from the scan line SL.

The storage capacitor Cst is connected between the second transistor T2 and a driving voltage line PL and may store a voltage corresponding to a difference between a voltage received from the second transistor T2 and a first power voltage ELVDD supplied to the driving voltage line PL.

The first transistor T1 has an electrode connected to the driving voltage line PL and the storage capacitor Cst and another electrode connected to the display element DE. The first transistor may be configured to control a driving current flowing through the display element DE from the driving voltage line PL in response to a voltage value stored in the storage capacitor Cst. The display element DE may have an electrode connected to the first transistor T1 and may be configured to emit light of a luminance that depends on the driving current. An opposing electrode of the display element DE may receive a second power voltage ELVSS.

In FIG. 3, the pixel circuit PC includes two transistors and one storage capacitor, but in other embodiments, the pixel circuit PC may include more transistors and/or more storage capacitors.

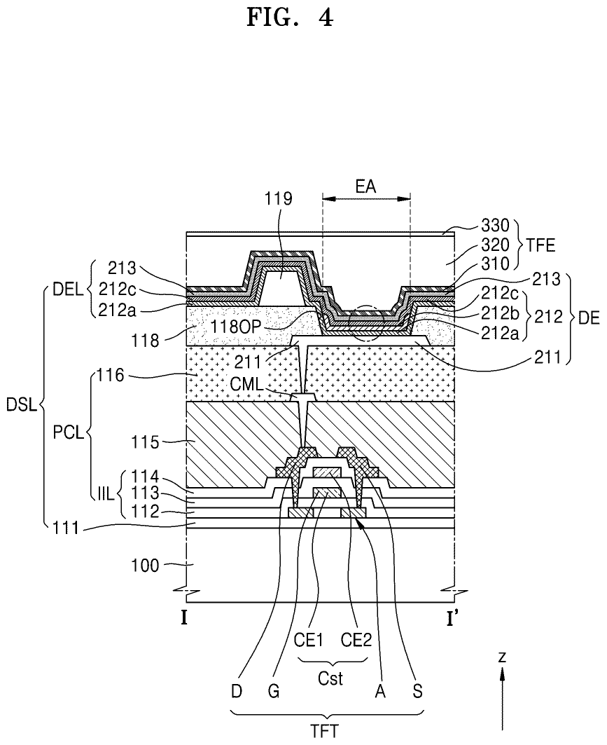

FIG. 4 is a cross-sectional view of a portion of the display device 1 taken along a line I-I′ shown in FIG. 1. As described above, the display device 1 may include the display panel 10. The display panel 10 may include the substrate 100, the display layer DSL, the encapsulation layer TFE, the touch sensor layer TSL, and the optical functional layer OFL. The touch sensor layer TSL and the optical functional layer OFL are not illustrated in FIG. 4 for convenience of description.

The substrate 100 may include glass or a polymer resin, such as polyethersulfone, polyarylate, polyetherimide, polyethylene naphthalate, polyethylene terephthalate, polyphenylene sulfide, polyimide, polycarbonate, cellulose triacetate, or cellulose acetate propionate. The substrate 100 including the polymer resin may be flexible, rollable, or bendable. The substrate 100 may have a multi-layer structure including a base layer including the polymer resin and a barrier layer (not shown). The display layer DSL may be disposed on the substrate 100. The display layer DSL may include a buffer layer 111, a pixel circuit layer PCL, and a display element layer DEL.

The buffer layer 111 may include an inorganic insulating material, such as silicon nitride, silicon oxynitride, or silicon oxide and may be a single layer or multi-layer including one or more of the above-mentioned inorganic insulating materials. The pixel circuit layer PCL may be disposed on the buffer layer 111. The pixel circuit layer PCL may include a transistor TFT that is part of a pixel circuit. The pixel circuit layer PCL may further include an inorganic insulating layer IIL, a first planarization layer 115, and a second planarization layer 116, which are arranged below and/or on components of the transistor TFT. The inorganic insulating layer IIL may include a first gate insulating layer 112, a second gate insulating layer 113, and an interlayer insulating layer 114.

The transistor TFT includes a semiconductor layer A, and the semiconductor layer A may include polysilicon. Alternatively, the semiconductor layer A may include amorphous silicon, an oxide semiconductor, or an organic semiconductor. The semiconductor layer A may include a channel region and may include a drain region and a source region, which are on opposite sides of the channel region. A gate electrode G may overlap the channel region.

The gate electrode G may include a low-resistance metal material. The gate electrode G may include a conductive material including molybdenum (Mo), aluminum (Al), copper (Cu), or titanium (Ti). The gate electrode G may be formed in a multi-layer or single layer including the conductive material(s).

The first gate insulating layer 112 between the semiconductor layer A and the gate electrode G may include an inorganic insulating material, such as silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), and/or zinc oxide (ZnOₓ). ZnOₓ may be zinc oxide (ZnO) and/or zinc peroxide (ZnO₂).

The second gate insulating layer 113 may cover the gate electrode G. Like the first gate insulating layer 112, the second gate insulating layer 113 may include an inorganic insulating material such as SiO₂, SiNx, SiON, Al₂O₃, TiO₂, Ta₂O₅, HfO₂, and/or ZnOₓ. ZnOₓ may be ZnO and/or ZnO₂.

An upper electrode CE2 of the storage capacitor Cst may be above the second gate insulating layer 113. The upper electrode CE2 may overlap the gate electrode G therebelow. Here, the upper electrode CE2 and the gate electrode G, which overlap with the second gate insulating layer 113 therebetween, may form the storage capacitor Cst of the pixel circuit. In other words, the gate electrode G may operate as a lower electrode CE1 of the storage capacitor Cst. As such, the storage capacitor Cst and the transistor TFT may overlap each other. According to some other embodiments, the storage capacitor Cst may not overlap the transistor TFT.

The upper electrode CE2 may include aluminum (AI), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and the upper electrode CE2 may be a single layer or multi-layer including such a material.

The interlayer insulating layer 114 may cover the upper electrode CE2. The interlayer insulating layer 114 may include SiO₂, SiNx, SiON, Al₂O₃, TiO₂, Ta₂O₅, HfO₂, or ZnOₓ. ZnOₓ may be ZnO and/or ZnO₂. The interlayer insulating layer 114 may be a single layer or multi-layer including the inorganic insulating material described above.

A drain electrode D and a source electrode S may each be located on the interlayer insulating layer 114. The drain electrode D and the source electrode S may include a material having good conductivity. The drain electrode D and the source electrode S may include a conductive material including Mo, Al, Cu, or Ti and may be a multi-layer or single layer structure including the conductive material. According to an embodiment, the drain electrode D and the source electrode S may have a multi-layer structure of Ti/Al/Ti. The drain electrode D and the source electrode S may extend through respective contact holes in the inorganic insulating layer IIL to respectively contact the drain region and the source region of the semiconductor layer A.

The first planarization layer 115 may cover the drain electrode D and the source electrode S. The first planarization layer 115 may be an organic insulating layer. The first planarization layer 115 may include an organic insulating material such as a general-purpose polymer, for example, polymethylmethacrylate (PMMA) or polystyrene (PS), a polymer derivate having a phenol-based group, an acrylic-based polymer, an imide-based polymer, an arylether-based polymer, an amide-based polymer, a fluorine-based polymer, a p-xylene-based polymer, a vinyl alcohol-based polymer, or a blend thereof.

A connection electrode CML may be arranged on the first planarization layer 115. Here, the connection electrode CML may be connected to the drain electrode D or source electrode S via a contact hole in the first planarization layer 115. The connection electrode CML may include a material having good conductivity. The connection electrode CML may include a conductive material including Mo, Al, Cu, or Ti, and may be formed as a multi-layer or single layer structure including the conductive material. According to an embodiment, the connection electrode CML may have a multi-layer structure of Ti/Al/Ti.

The second planarization layer 116 may cover the connection electrode CML. The second planarization layer 116 may be an organic insulating layer. The second planarization layer 116 may include an organic insulating material such as a general-purpose polymer, for example, polymethylmethacrylate (PMMA) or polystyrene (PS), a polymer derivate having a phenol-based group, an acrylic-based polymer, an imide-based polymer, an arylether-based polymer, an amide-based polymer, a fluorine-based polymer, a p-xylene-based polymer, a vinyl alcohol-based polymer, or a blend thereof.

The display element layer DEL may be disposed on the pixel circuit layer PCL. The display element layer DEL may include the display element DE. The display element DE may be an organic light-emitting diode (OLED). A pixel electrode 211 of the display element DE may be electrically connected to the connection electrode CML via a contact hole in the second planarization layer 116.

The pixel electrode 211 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). According to another embodiment, the pixel electrode 211 may include a reflective layer including silver (Ag), magnesium (Mg), aluminum (AI), platinum (Pt), palladium (Pd), gold (Au), nickel (Ni), neodymium (Nd), iridium (Ir), chromium (Cr), or a compound or alloy thereof. According to another embodiment, the pixel electrode 211 may further include a layer formed of ITO, IZO, ZnO, or In₂O₃ on or below the reflective layer.

A pixel-defining layer 118 having an opening 118OP exposing a center portion of the pixel electrode 211 may be on the pixel electrode 211. The pixel-defining layer 118 may include an organic insulating material and/or an inorganic insulating material. The opening 118OP may define an emission area EA for light emitted from the display element DE. For example, a width of the opening 118OP may correspond to a width of the emission area EA of the display element DE.

A spacer 119 may be on the pixel-defining layer 118. The spacer 119 may be used to prevent damage to the substrate 100 during manufacturing the display device 1. A mask sheet may be used while manufacturing the display panel 10, and at this time, the spacer 119 may prevent the mask sheet from entering into the opening 118OP of the pixel-defining layer 118 or prevent a portion of the substrate 100 from being damaged or broken by the mask sheet while depositing a deposition material on the substrate 100 close to the pixel-defining layer 118.

The spacer 119 may include an organic insulating material such as polyimide. Alternatively, the spacer 119 may include an inorganic insulating material such as silicon nitride or silicon oxide or may include an organic insulating material and an inorganic insulating material.

According to an embodiment, the spacer 119 may include a material different from the pixel-defining layer 118. According to another embodiment, the spacer 119 may include the same material as the pixel-defining layer 118, and in this case, the pixel-defining layer 118 and the spacer 119 may be formed together during a mask process using a half-tone mask or the like.

An intermediate layer 212 may be on the pixel-defining layer 118. The intermediate layer 212 may include an emission layer 212b in the opening 118OP in the pixel-defining layer 118. The emission layer 212b may include a high-molecular weight organic material or a low-molecular weight organic material, which emits light of a certain color.

A first functional layer 212a and a second functional layer 212c may be respectively below and on the emission layer 212b. The first functional layer 212a may include, for example, a hole transport layer (HTL) or may include an HTL and a hole injection layer (HIL). The second functional layer 212c may include an electron transport layer (ETL) and/or an electron injection layer (EIL). Like an opposing electrode 213 described below, the first functional layer 212a and/or the second functional layer 212c may be a common layer formed to entirely cover the substrate 100.

The opposing electrode 213 may include a conductive material with a low work function. For example, the opposing electrode 213 may include a (semi-)transparent layer including Ag, Mg, Al, Pt, Pd, Au, Ni, Nd, Ir, Cr, lithium (Li), calcium (Ca), or an alloy thereof. The opposing electrode 213 may further include a layer including ITO, IZO, ZnO, or In₂O₃. on the (semi-)transparent layer including the above material.

According to some embodiments, a capping layer (not shown) may be on the opposing electrode 213. The capping layer may include lithium fluoride (LiF), an inorganic material, and/or an organic material.

The encapsulation layer TFE may be on the opposing electrode 213. The encapsulation layer TFE may be on the display element layer DEL and cover the display element layer DEL. The encapsulation layer TFE may include at least one inorganic encapsulation layer and at least one organic encapsulation layer, and FIG. 4 illustrates an embodiment of the encapsulation layer TFE that includes a first inorganic encapsulation layer 310, an organic encapsulation layer 320, and a second inorganic encapsulation layer 330, which are sequentially stacked on each other.

The first inorganic encapsulation layer 310 and second inorganic encapsulation layer 330 may include one or more inorganic materials from among aluminum oxide, titanium oxide, tantalum oxide, hafnium oxide, zinc oxide, silicon oxide, silicon nitride, and silicon oxynitride. The organic encapsulation layer 320 may include a polymer-based material. Examples of the polymer-based material may include an acrylic resin, an epoxy resin, polyimide, and polyethylene. According to an embodiment, the organic encapsulation layer 320 may include acrylate. The organic encapsulation layer 320 may be formed by curing monomer or applying polymer. The organic encapsulation layer 320 may be transparent.

Although not illustrated, a touch sensor layer described above may be on the encapsulation layer TFE, and an optical functional layer may be on the touch sensor layer.

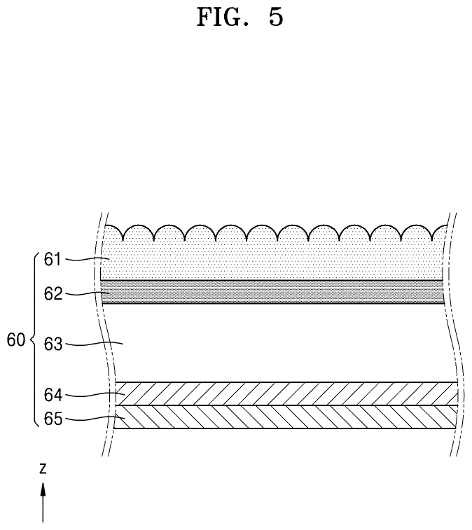

FIG. 5 is a cross-sectional view of the cover panel 60 according to an embodiment. FIG. 5 may particularly be an enlarged view of a portion of the cover panel 60 of FIG. 2. In the embodiment of FIG. 5, the cover panel 60 may include an embossed adhesive layer 61, a film layer 62, a buffer adhesive layer 63, a metal layer 64, and a frame layer 65.

The embossed adhesive layer 61 may be positioned below the display panel 10. According to an embodiment, the embossed adhesive layer 61 may include an embossed structure on one surface. For example, the embossed adhesive layer 61 may include, on a surface (e.g., facing a +z direction in FIG. 5) contacting the display panel 10, a plurality of protrusions protruding towards the display panel 10, i.e., the embossed structure. A cross-sectional shape of the embossed structure may be semicircular as shown in FIG. 5, but may be triangular or have any other shape. The embossed adhesive layer 61, including the embossed structure, may prevent generation of bubbles. Also, the embossed structure may enable the embossed adhesive layer 61 to closely adhered to a lower surface of the display panel 10.

The film layer 62 may be disposed below the embossed adhesive layer 61. According to an embodiment, the film layer 62 may include polyethylene terephthalate (PET). Also, the film layer 62 may include a light blocking material. For example, the film layer 62 may include black dye or pigment. Accordingly, the film layer 62 may block light and prevent an internal structure from being visible from below the cover panel 60. In addition, the film layer 62 may block light introduced from or into a lower portion of the display panel 10.

The buffer adhesive layer 63 may be disposed below the film layer 62. The buffer adhesive layer 63 may be an adhesive layer adhering components of the cover panel 60 to each other, for example, a pressure sensitive adhesive (PSA), and the buffer adhesive layer 63 may also perform a buffering function. According to an embodiment, the buffer adhesive layer 63 may include an acryl-based polymer compound. Also, the buffer adhesive layer 63 may further include at least one of polyurethane acrylate, rubber, and polystyrene. Here, polyurethane acrylate may include at least one of toluene diisocyanate (TDI), isoporon diisocyanate (IPDI), polypropylene glycol (PPG), and polytetramethalene ether glycol (PTMEG). When the buffer adhesive layer 63 further includes polyurethane acrylate, about 0.05 wt % to about 20 wt % of polyurethane acrylate may be included. Accordingly, the buffering function of the buffer adhesive layer 63 may be further reinforced to alleviate effects of an impact.

Also, according to an embodiment, the buffer adhesive layer 63 may be transparent. In this case, the film layer 62 may perform a light blocking function and the buffer adhesive layer 63 may perform the buffering function.

The metal layer 64 may be below the buffer adhesive layer 63. In other words, the buffer adhesive layer 63 may be arranged such that one surface, e.g., an upper surface, is in direct contact with the film layer 62, and another surface, e.g., a lower surface, is in direct contact with the metal layer 64. The buffer adhesive layer 63 may be provided as a single layer between the film layer 62 and the metal layer 64. According to an embodiment, the metal layer 64 may include a metal having excellent thermal conductivity, such as Cu, Al, or Ag. Accordingly, the metal layer 64 may perform a heat dissipation function. Also, the metal layer 64 may block electromagnetic waves and accordingly shield the display panel 10 from electromagnetic interference (EMI). Hereinafter, a case where the metal layer 64 includes Cu will be mainly described.

The frame layer 65 may be disposed below the metal layer 64. According to an embodiment, an insulating layer may be arranged between the frame layer 65 and the metal layer 64, but embodiments are not limited thereto, and the insulating layer may be omitted as illustrated in FIG. 5.

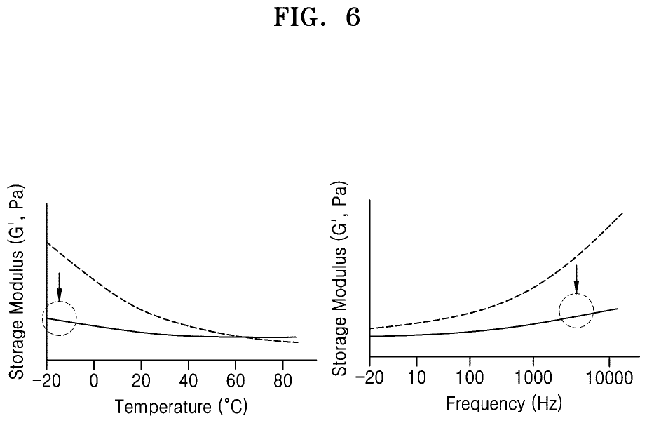

FIG. 6 is a graph of a storage modulus of the buffer adhesive layer 63, according to an embodiment.

Referring to FIG. 6, physical properties developed during high-speed movement of the buffer adhesive layer 63 may be measured by using time-temperature superposition (TTS). In particular, when the buffer adhesive layer 63 has viscoelastic properties, the viscoelastic properties may exhibit a strong dependence on temperature. According to TTS, a change in a storage modulus G′ according to frequency may be derived through a change in the viscoelastic properties, i.e., the storage modulus G′, of the buffer adhesive layer 63 according to temperature. A left graph in FIG. 6 illustrates dependence of the storage modulus G′ on temperature and a right graph of FIG. 6 illustrates dependence of the storage modulus G′ on a frequency of oscillatory motion. Also, in the graphs of FIG. 6, solid lines represent the buffer adhesive layer 63 according to an embodiment, and broken lines represent an adhesive layer according to a comparative example.

The buffering function of the buffer adhesive layer 63 may be reinforced and improved when the value of the storage modulus G′ is low in a high-frequency region, e.g., in a region of about 1000 Hz to about 5000 Hz. The storage modulus G′ in the high-frequency region may correspond to the storage modulus G′ measured in a low-temperature region, e.g., about −20° C. to about 40° C. According to an embodiment, a value of the storage modulus G′ of the buffer adhesive layer 63, measured at −20° C., may be greater than about 0 MPa but not greater than about 10 MPa. According to an embodiment, a value of the storage modulus G′ of the buffer adhesive layer 63, measured at −40° C., may be about 2 MPa to about 30 MPa. As such, the buffer adhesive layer 63 according to an embodiment may have a lower value of storage modulus G′ in the low-temperature region than the adhesive layer according to the comparative example. This may indicate that the buffer adhesive layer 63 has a lower value of storage modulus G′ in the high-frequency region than the adhesive layer according to the comparative example. In this case, the buffer adhesive layer 63 may have an improved buffering function against an impact.

The comparative example may include a plurality of layers that provide impact buffering. In the cover panel 60, the buffer adhesive layer 63 with the improved buffering function may replace a plurality of layers. For example, the cover panel 60 may not include at least one layer from among a cushion layer including foam, a film layer including polyimide, and an adhesive layer connecting the cushion layer and the film layer to each other. In other words, the cover panel 60 may replace at least one of such layers with the buffer adhesive layer 63.

The cover panel 60 may have fewer layers and therefore a simplified structure, and thus, manufacturing processes for the cover layer 60 may be simplified compared to the manufacturing process for other cover structures. In addition, manufacturing costs of the display device 1 including the cover layer 60 may be reduced. Also, flatness of a display surface of the display device 1 may be improved. In particular, when a cushion layer including foam is disposed below the display panel 10, an uneven surface of the cushion layer may be transferred and visible on the display panel 10 disposed on the cushion layer, due to a difference in pores of the foam of the cushion layer. According to an embodiment, the buffer adhesive layer 63 does not include pores, and thus may perform the buffering function while improving flatness of the display surface of the display device 1 without transferring an uneven surface to the display panel 10.

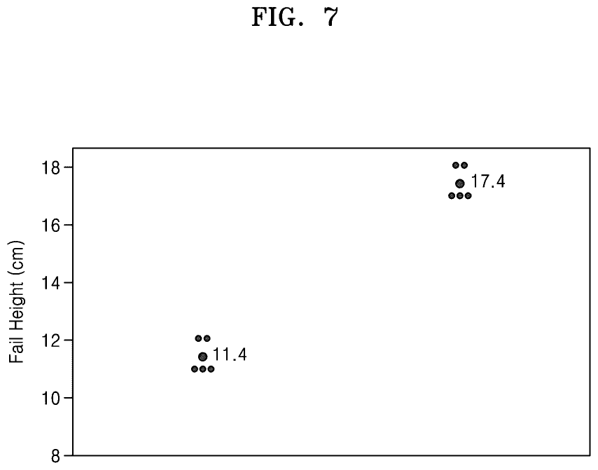

FIG. 7 is a graph of a ball drop test of the cover panel 60 according to an embodiment.

FIG. 7 schematically illustrates ball drop test values of the cover panel 60 including the buffer adhesive layer 63, according to an embodiment, and a cover panel according to a comparative example. The ball drop test is a test that measures a height from which a dropped ball damages a panel. The cover panel according to the comparative example may include, for example, a cushion layer including foam. In this case, a ball drop height at which a panel is damaged is measured to be an average value (left) of about 11.4 cm. A ball drop height at which a panel is damaged in the cover panel 60 including the buffer adhesive layer 63, according to an embodiment, is measured to be an average value (right) of about 17.4 cm. In other words, when the buffer adhesive layer 63 is included, the structure of the layers of the cover panel 60 may be simplified and the buffering function may be improved.

According to an embodiment, the buffer adhesive layer 63 may further include a light blocking material. For example, the light blocking material may include dye, pigment, or carbon black. According to an embodiment, the buffer adhesive layer 63 may include about 3 wt % to about 5 wt % of the light blocking material. Accordingly, the buffer adhesive layer 63 may perform a light blocking function. For example, when the buffer adhesive layer 63 includes about 3 wt % to about 5 wt % of light blocking material, the buffering function of the buffer adhesive layer 63 does not deteriorate, and the buffer adhesive layer 63 may perform the light blocking function. In this case, the film layer 62 described above may be omitted, but the disclosure is not limited thereto, and the buffer adhesive layer 63 may perform the light blocking function together with the film layer 62.

According to an embodiment, the buffer adhesive layer 63 may further include a heat dissipation filler. The heat dissipation filler may include at least one of, for example, silica (SiO₂) and alumina (Al₂O₃). In this case, the buffer adhesive layer 63 may perform a heat dissipation function. In other words, the buffer adhesive layer 63 may externally discharge heat generated from the display panel 10 and/or the cover panel 60.

As described above, a cover panel with reinforced impact resistance and improved surface flexure may be provided.

A structure of a display device may also be simplified, and manufacturing processes may be simplified.

The effects of the disclosure are not limited to those mentioned above, and other effects that are not mentioned may be clearly understood by one of ordinary skill in the art from the scope of claims.

The embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, those of ordinary skill in the art will understand that various changes in form and details may be made therein without departing from the spirit and scope as defined by the following claims.

What is claimed is:

1. A display device comprising:
a display panel configured to display an image on a surface; and
a cover panel on another surface of the display panel that faces the surface of the display panel that displays the image,
wherein the cover panel comprises a buffer adhesive layer in which storage modulus measured at −20° C. is greater than about 0 MPa but not greater than about 10 MPa.

2. The display device of claim 1, wherein the storage modulus of the buffer adhesive layer, measured at −40° C., is about 2 MPa to about 30 MPa.

3. The display device of claim 1, wherein the buffer adhesive layer comprises at least one of polyurethane acrylate, rubber, and polystyrene.

4. The display device of claim 3, wherein the buffer adhesive layer further comprises at least one of toluene diisocyanate (TDI), isoporon diisocyanate (IPDI), polypropylene glycol (PPG), and polytetramethalene ether glycol (PTMEG).

5. The display device of claim 3, wherein the buffer adhesive layer contains about 0.05 wt % to about 20 wt % of the polyurethane acrylate.

6. The display device of claim 3, wherein the buffer adhesive layer further comprises an acryl-based polymer compound.

7. The display device of claim 1, wherein the cover panel further comprises a film layer in contact with an upper portion of the buffer adhesive layer.

8. The display device of claim 7, wherein the cover panel further comprises a metal layer in contact with a lower portion of the buffer adhesive layer.

9. The display device of claim 8, wherein the metal layer comprises copper (Cu).

10. The display device of claim 1, wherein the buffer adhesive layer further comprises a pigment that blocks light.

11. The display device of claim 10, wherein the buffer adhesive layer includes about 3 wt % to about 5 wt % of the pigment.

12. The display device of claim 1, wherein the buffer adhesive layer further comprises a heat dissipation filler for heat dissipation.

13. The display device of claim 12, wherein the heat dissipation filler comprises silica or alumina.

14. A display device comprising:
a display panel that is bent in a U shape so that a first portion of the display panel and a second portion of the display panel face each other; and
a cover panel between the first portion and the second portion,
wherein the cover panel comprises a buffer adhesive layer in which storage modulus measured at −20° C. is greater than about 0 MPa but not greater than about 10 MPa.

15. The display device of claim 14, wherein the storage modulus of the buffer adhesive layer, measured at −40° C., is about 2 MPa to about 30 MPa.

16. The display device of claim 14, wherein the buffer adhesive layer comprises at least one of polyurethane acrylate, rubber, and polystyrene.

17. The display device of claim 16, wherein the buffer adhesive layer further comprises at least one of toluene diisocyanate (TDI), isoporon diisocyanate (IPDI), polypropylene glycol (PPG), and polytetramethalene ether glycol (PTMEG).

18. The display device of claim 16, wherein the buffer adhesive layer contains about 0.05 wt % to about 20 wt % of the polyurethane acrylate.

19. The display device of claim 14, wherein the buffer adhesive layer further comprises a pigment that blocks light.

20. The display device of claim 14, wherein the buffer adhesive layer further comprises a heat dissipation filler for heat dissipation.
